(19) United States
(12) Patent Application Publication
(10) Pub. No.: US 2019/0319106 A1
(43) Pub. Date: Oct. 17, 2019

(54) SEMICONDUCTOR DEVICE COMPRISING 3D CHANNEL REGION AND METHOD OF MANUFACTURING THE SAME

(71) Applicant: DB HiTek Co., Ltd., Seoul (KR)

(72) Inventor: Yong-Keon CHOI, Gyeonggi-do (KR)

(21) Appl. No.: 16/216,804

(22) Filed: Dec. 11, 2018

(30) Foreign Application Priority Data
Apr. 11, 2018 (KR) 10-2018-0041998

(51) Int. Cl. H01L 29/423; H01L 29/66; H01L 29/78; H01L 29/06

(52) U.S. Cl. CPC H01L 29/42356; H01L 29/0696; H01L 29/7813; H01L 29/66734

(57) ABSTRACT

A semiconductor device having a three-dimensional (3D) channel region and a method of manufacturing the same. More particularly, in the semiconductor device and method of manufacturing a vertically extended path of a lower surface of a gate is configured in 3D such that a vertically extended path of a channel region is also configured in 3D.

### CROSS-REFERENCE TO RELATED APPLICATION

This application claims the benefit of Korean Patent Application No. 2018-0041998, filed Apr. 11, 2018, which is hereby incorporated by reference in its entirety into this application.

### BACKGROUND OF THE INVENTION

### 1. Technical Field

The present invention relates to a semiconductor device having a three-dimensional (3D) channel region and a method of manufacturing the same. More particularly, the present invention relates to a semiconductor device and a method of manufacturing the same, in which a lower surface of a gate has a vertically extended region or path (e.g., in a second direction) that is “configured in 3D,” such that a channel region also has a vertically extended region or path that is also “configured in 3D.”

### 2. Description of the Related Art

A laterally diffused metal oxide semiconductor (LDMOS) transistor has a rapid switching response and high input impedance. Thus, the LDMOS transistor is widely used in power device applications. Hereinafter, a general LDMOS transistor structure will be described in detail.

Hereinafter, each configuration will be described with reference to a first direction (e.g., a “vertical” direction) and a second direction (e.g., a “horizontal” direction). The term “first direction” refers to a direction from a source region to an adjacent drain region, and the “second direction” refers to a direction orthogonal (e.g., perpendicular) to an uppermost surface of the source and/or the drain and to the first direction. The directions can be more clearly understood with reference to the drawings according to an embodiment of the present invention.

FIG. 1 is a plan view illustrating an LDMOS device of the related art; FIG. 2 is a cross-sectional view illustrating the LDMOS device of FIG. 1, taken along line F-F′; and FIG. 3 is a cross-sectional view illustrating the LDMOS device of FIG. 1, taken along line G-G′. Hereinafter, an LDMOS device 900 of the related art will be described in detail with reference to FIGS. 1 to 3.

Referring to FIGS. 1 to 3, the LDMOS device 900 of the related art is has a gate 910 on a semiconductor substrate, and includes a source region 920 and a drain region 930 apart from each other on the substrate. In addition, a body contact region 940 is at a position adjacent to and in contact with the source region 920. Furthermore, a gate dielectric layer 950 is between the gate 910 and the substrate.

When a predetermined positive voltage is applied to the gate 910, electrons are accumulated adjacent to a lower surface of the gate dielectric layer 950, whereby an inversion layer is formed, providing a channel region CR (see FIG. 3), which is a path for charge carriers (e). At this point, the charge carriers (e) move from the source region 920 to the drain region 930 through the channel region CR providing a current flow.

In the semiconductor device 900 of the related art, the charge carriers (e) move in the first direction through the channel region CR as shown, and the channel region CR is substantially a two-dimensional (2D) region along the horizontal direction. That is, the charge carriers (e) move only through the 2D channel region. Thus, the number of charge carriers (e) moving through the channel region CR is limited, which makes it difficult to improve the current density.

In order to solve the above-mentioned problems, the present invention provide a semiconductor device and a method of manufacturing the same, which can contribute to the improvement of current density by increasing the channel region area and/or forming a three-dimensional (3D) channel region.

### SUMMARY OF THE INVENTION

Accordingly, the present invention has been made keeping in mind the above problems occurring in the related art, and the present invention relates to a semiconductor device having a 3D channel region and a method of manufacturing the same, in which a lower surface of a gate has an extended path in a second (vertical) direction (e.g., is “configured in 3D,” such that a channel region has an extended path in a second (vertical) direction (e.g., is also “configured in 3D”). As a result, the area for charge carriers (e.g., electrons) to move from the source to the drain (e.g., in a first direction) increases, thereby increasing the number of moving charge carriers, and thus, improving the current density due to a decrease in the specific on-resistance.

In addition, the present invention relates to a semiconductor device having a 3D channel region and a method of manufacturing the same, in which a plurality of trenches in a substrate are spaced apart from each other, and a gate on or above the substrate and at least partially in the trenches has a plurality of vertically extended regions, such that the channel portions are below the plurality of vertical extended gate region. As a result, an area of the channel region is increased by increasing the area of the channel portions.

In order to achieve the above objects, the present invention is realized by embodiments having the following features.

A semiconductor device having a three-dimensional (3D) channel region, the device includes a first conductive-type semiconductor substrate, a gate on or above the substrate, a first conductive-type body region on a first side of the gate, a second conductive-type drift region on a second side of the gate, a second conductive-type source region at the surface of the substrate and in the body region, and a second conductive-type drain region at the surface of the substrate and in the drift region, wherein a lower surface of the gate extends vertically, such that the gate has a 3D path.

The device may further include a 3D channel region below the gate in a manner that substantially corresponds to the gate.

The gate may include a plurality of vertically extended regions.

The device may further include a channel portion below the plurality of vertical extended regions.

The gate may include a gate dielectric layer in a predetermined pattern on the substrate and a gate electrode on the gate dielectric layer.

A semiconductor device having a three-dimensional (3D) channel region, the device includes a first conductive-type semiconductor substrate, a gate on or above the substrate; a first conductive-type body region on a first side of the gate, a second conductive type drift region on a second side of the gate, a second conductive type source region at the surface of the substrate and in the body region, and a second conductive-type drain region at the surface of the substrate and in the drift region, wherein the gate includes a plurality of vertically extended regions.

The gate may further include a plurality of horizontally extended regions, each connected to an end of at least one of the vertically extended regions.

The gate may include a gate dielectric layer in a predetermined pattern on the substrate and a gate electrode on the gate dielectric layer.

The device may further include in the body region, a first channel portion below the plurality of horizontally extended regions, and a second channel portion below the plurality of vertically extended regions.

A method of manufacturing a semiconductor device having a 3D channel region, the method includes forming a plurality of trenches in a substrate and spaced apart from each other; forming a drift region in the substrate; depositing a gate dielectric layer and a gate film on the substrate and in the trenches; and etching the gate film corresponding to a position of a first conductive-type body region; and forming the body region.

The gate dielectric layer and a gate electrode may extend vertically, and the gate dielectric layer and the gate electrode may have a 3D path.

The method may further include forming a source region in the substrate in the body region; and forming a drain region in the substrate in the drift region.

A channel region having a 3D charge carrier movement path may be formed.

A method of manufacturing a semiconductor device having a 3D channel region, the method includes forming a plurality of trenches in a substrate and spaced apart from each other, forming a drift region in the substrate, depositing a gate dielectric layer and a gate film on the substrate and in the plurality of trenches, forming a body region in the substrate, and forming a gate by etching the gate dielectric layer and the gate film, wherein a portion of the gate that is in the trenches includes a plurality of vertically extended regions.

The method may further include forming a source region in the substrate and in the body region; and forming a drain region in the substrate and in the drift region.

A channel region may be formed that includes vertically extended channel portions below the plurality of vertically extended regions.

The gate outside the plurality of trenches may further comprise a plurality of horizontally extended regions and connected to at least an end of the vertically extended regions.

The channel region may further comprise a channel portion below the plurality of horizontally extended regions. In various embodiments of the present invention, the gate overlaps the field oxide.

The present invention has the following effects with the above-described configuration(s).

According to various embodiments of the present invention, a lower surface of a gate extends vertically, such that the gate has a 3D path, and a channel region also has a 3D path. Accordingly, an area in which charge carriers move from a source region to a drain region in a horizontal direction (e.g., a first direction) is increased. As a result, the number of charge carriers is increased, and thus, the current density is improved due to the decrease of the specific on-resistance of the channel region.

In addition, according to various embodiments of the present invention, a plurality of trenches are in a substrate and are spaced apart from each other, and a portion of the gate that is in the trenches comprises a plurality of vertically extended regions. Accordingly, the channel portions below the plurality of vertical extended regions increase an area of the channel region along the second (e.g., vertical) direction by advantageously increasing areas of the channel portions having vertically extended regions.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a plan view illustrating a laterally diffused metal oxide semiconductor (LDMOS) device of the related art;

FIG. 2 is a cross-sectional view illustrating the semiconductor device of FIG. 1, taken along line F-F′ in FIG. 1;

FIG. 3 is a cross-sectional view illustrating the semiconductor device of FIG. 1, taken along line G-G′ in FIG. 1;

FIG. 4 is a plan view illustrating a semiconductor device, according to embodiments of the present invention;

FIG. 5 is a cross-sectional view illustrating the semiconductor device of FIG. 4, taken along line a-a′ in FIG. 4;

FIG. 6 is a cross-sectional view illustrating the semiconductor device of FIG. 4, taken along line b-b′ in FIG. 4;

FIG. 7 is a cross-sectional view illustrating the semiconductor device of FIG. 4, taken along line c-c′ in FIG. 4;

FIG. 8 is a cross-sectional view illustrating the semiconductor device of FIG. 4, taken along line d-d′ in FIG. 4; and

FIGS. 9 to 12 are diagrams illustrating a method of manufacturing a semiconductor device, according to embodiments of the present invention.

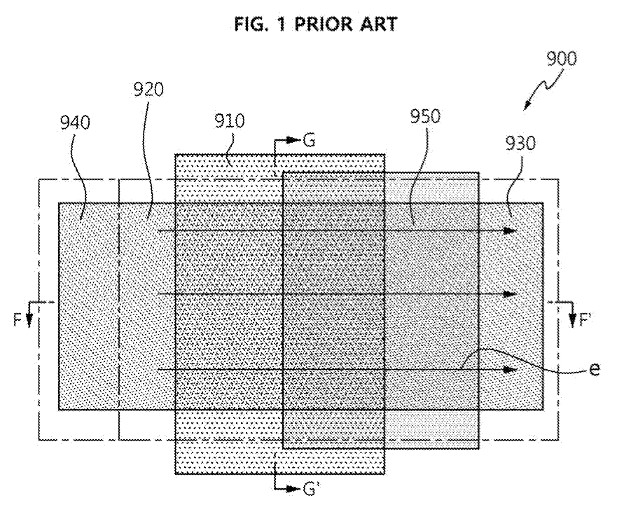

### DESCRIPTION OF THE PREFERRED EMBODIMENTS

Hereinafter, embodiments of the present invention will be described in detail with reference to the accompanying drawings. Various changes to the following embodiments are possible and the scope of the present invention is not limited to the following embodiments. The patent right of the present invention should be defined by the scope and spirit of the invention as disclosed in the accompanying claims. In addition, the embodiments of the present invention are intended to fully describe the present invention to a person having ordinary knowledge in the art to which the present invention pertains.

Hereinafter, when it is described that a component (or a layer) is referred to as being “on” another component (or another layer), it should be understood that the component is directly on the other component or one or more intervening components (or layers) are also present. In contrast, when it is described that a component is referred to as being directly on to another component, it should be understood that there is (are) no intervening component(s) present. In addition, terms indicating positions, such as, being located “on”, “upper”, “lower”, “one side”, and “the other side” are intended to mean a relative position of components.

In addition, it will be understood that, although ordinal numbers such as first, second, third, etc., may be used herein to describe various elements, components, regions, layers, and/or sections, these terms are used merely for ease of reference and/or antecedent basis for particular elements, regions, layers, and/or sections. Accordingly, these terms should not be construed to describe of imply a particular sequence or ordering of elements, components, regions, layers and/or sections unless explicitly stated. For example, a second element is not based on a first element, but corresponds to an element independent of each other. Accordingly, the terms such as first, second, third, etc. are merely used for convenience of explanation.

In addition, when a certain embodiment may be implemented differently, a specific process order may be performed differently from the described order. For example, two consecutively described processes may be performed substantially at the same time or performed in an order opposite to the described order.

Furthermore, hereinafter, each configuration will be described with reference to a “first direction” and a “second direction”. The term “first direction” means a direction from a source region to an adjacent drain region (e.g., a horizontal direction), and the term “second direction” means to a direction orthogonal to the first direction (e.g., a vertical direction and/or a direction perpendicular to the first direction, but parallel with the thickness direction of the substrate). The directions can be more clearly understood with reference to the drawings according to embodiments of the present invention.

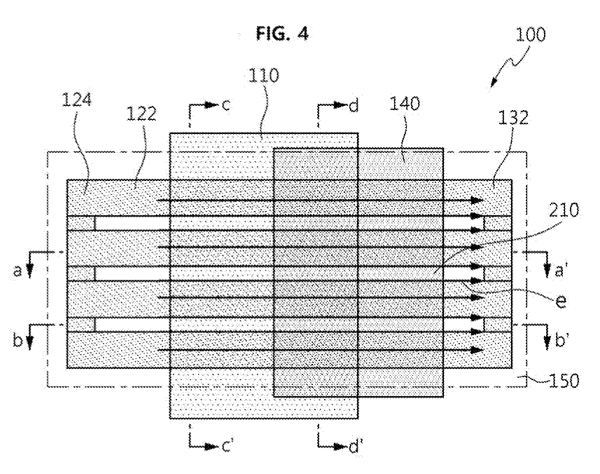

As used herein, the term “plate region” refers to a region where a field oxide 140 is on a substrate 102, and the term “gate formation region” refers to a region where a gate 110 is to be formed on the substrate 102. In addition, a portion of the gate 110, which is on and overlapping the field oxide 140 may be referred to as an “overlapping region” (see, e.g., FIG. 4).

As used herein, the phrase “second direction outside the overlapping region” means the second direction in the plate region and outside of the overlapping region, and the phrase “a second direction in the overlapping region” means the second direction in the overlapping region.

As used herein, the term “metal-oxide-semiconductor” (MOS) is a general term, and is not limited to metal with respect to the term metal (M), but may be made of various types of conductors. In addition, the term semiconductor (S) may be a substrate or a semiconductor structure, and the term oxide (O) is not limited to oxides but may include various types of insulating organic or inorganic materials.

Furthermore, a conductive-type or a doped region of the components may be defined as a p-type or an n-type depending on characteristics of a main (charge) carrier, but this is for convenience of explanation and a technical idea of the present invention is not limited to the examples. For example, hereinafter, a p-type or an n-type will be used as the more general term “first conductive-type” or “second conductive-type”, where the first conductive type means one of a p-type and an n-type, and the second conductive-type means the other of the p-type and the n-type.

It should be understood that terms “high concentration” and “low concentration” express a doping concentration of an impurity region and refer to relative doping concentrations of one component in comparison to other components.

Hereinafter, a semiconductor device having a three-dimensional (3D) channel region and a method of manufacturing the same according to embodiments of the invention will be described in detail with reference to the accompanying drawings.

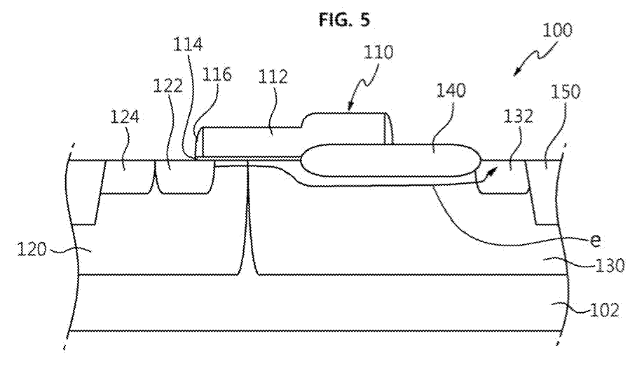

Referring to FIGS. 4 and 5, the semiconductor device 100 having the 3D channel region, according to the embodiments of the present invention includes a semiconductor substrate 102 (of FIG. 5) having a first conductivity type. The substrate 102 may be a p-type doped substrate, a p-type diffusion region in the substrate, or a p-type epitaxial layer epitaxially grown on the substrate. In addition, the substrate 102 may be configured with a well region (WELL) used as an active region, and the active region may be defined by an isolation layer 150. The isolation layer 150 may be formed by a shallow trench isolation (STI) method, which will be described later.

The gate 110 is on or above the substrate 102, such that the gate formation region is along the first (e.g., a horizontal) direction. The gate 110 includes a gate electrode 112 (see, e.g., FIG. 5). In addition, a gate dielectric layer 114 (FIG. 5) is between the gate electrode 112 and the substrate 102. That is, the gate electrode 112 may be on the gate dielectric layer 114. The gate dielectric layer 114 may comprise a material selected from the group consisting of a silicon oxide film, a high-κ dielectric film, and a combination thereof, and may be formed by ALD, CVD, or a PVD process.

In addition, one side or both sides of the gate electrode 112 may have a spacer 116 thereon. The spacer 116 may also comprise a material selected from the group consisting of a silicon oxide film, a high-κ dielectric film, and a combination thereof.

The gate 910 of the semiconductor device 900 of the related art will be described in detail once again before a detailed description of the gate 110 of the semiconductor device 100 according to embodiments of the present invention.

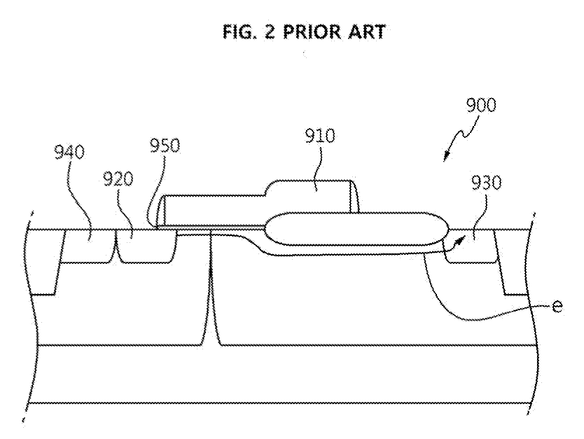

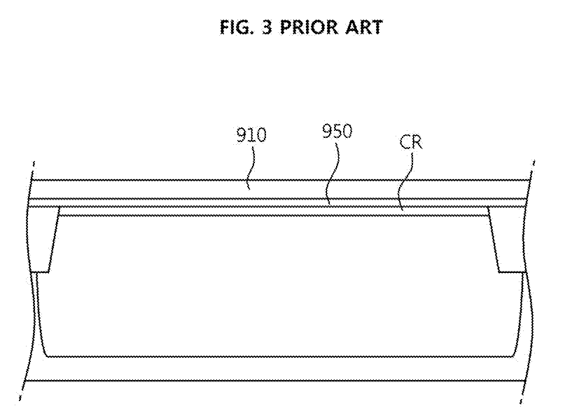

Referring to FIGS. 2 and 3, the semiconductor device 900 of the related art shows that the gate dielectric layer 950 which is on a lower surface of the gate device 910 and below the gate device 910 that extends substantially in a horizontal direction. Generally, when a predetermined positive voltage is applied to the gate terminal of the gate device 910, electrons are accumulated adjacent to the lower surface of the gate dielectric layer 950, whereby the inversion layer is formed, and the channel region CR is formed. At this point, the charge carriers (e.g., electrons) (e) move from the source region 920 to the drain region 930 through the channel region CR, providing a current flow.

Thus, the charge carriers (e) move in the first direction through the channel region CR (e.g., the charge carriers move from the source region 920 to the drain region 930), and the channel region CR is substantially configured as a two-dimensional (2D) region, along the horizontal direction shown in FIG. 3. Therefore, the charge carriers (e) only move in the 2D channel region CR, such that the number of moving charge carriers (e) is limited, which makes it difficult for the amount of current flowing in the channel region CR to exceed a certain level. As a result, there is a limit to improving current density.

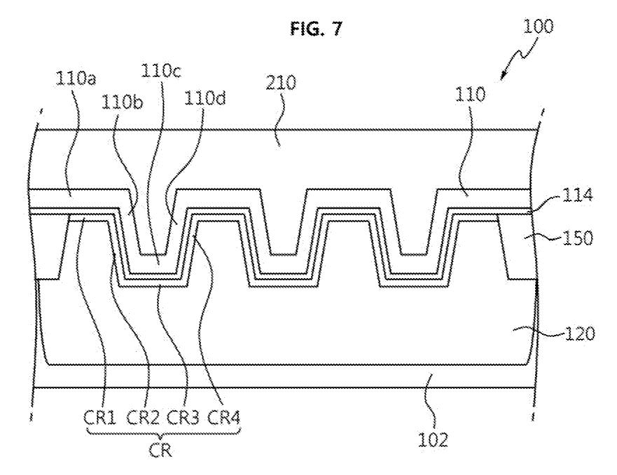

In order to solve the above problems of the related art, the gate 110 in a semiconductor device 100 according to embodiments of the present invention is provided such that a lower surface of the gate 110 has a 3D region along a vertical direction, as shown in FIG. 7.

In various embodiments of the present invention, the gate 110 includes a first gate region 110a that substantially extends in a horizontal direction, a plurality of vertically extended regions (e.g., a second gate region 110b and a fourth gate region 110d). Each of the plurality of vertically extended regions may extend obliquely (e.g., at a slant or an angle). For example, the second gate region 110b extends vertically from one end of the first gate region 110a away from an adjacent isolation layer 150. In addition, the gate 110 includes a third gate region 110c that extends substantially in a horizontal direction from a lower end of the second gate region 110b and away from the first gate region 110a. For example, the fourth gate region 110d extends vertically from one end of the third gate region 110c, from the one end of the third gate region 110c to an adjacent first gate region 110a, which may not be directly connected.

In addition, an upper end of the fourth gate region 110d is connected to the adjacent first gate region 110a, such that the first to fourth gate regions 110a to 110d repeat along the second-first direction. Therefore, as described above, the gate section 110, particularly the lower surface of the gate portion 110 extends in both horizontal and vertical directions. A path of the gate 110 changes as the path extends vertically in the 3D region or configuration, and the channel region CR below the gate 110 may also be configured as a 3D path.

In various embodiments, the body region 120 includes a first channel portion CR1 below the first gate region 110a that extends substantially in the horizontal direction, a second channel portion CR2 below the second gate region 110b that extends vertically from one end of the first channel portion CR1, a third channel portion CR3 below the third gate region 110c that extends substantially in the horizontal direction, and/or a fourth channel portion CR4 below the fourth gate region 110d that extends vertically from one end of the third channel portion CR3. Accordingly, the first to fourth channel portions CR1 to CR4 form a path substantially corresponding to the first to fourth gate regions 110a to 110d, as shown in FIG. 7.

Therefore, the semiconductor device 100 according to embodiments of the present invention is configured with not only the first channel portion CR1 and the third channel portion CR3 as provided in the conventional semiconductor device, but also configured with the second channel portion CR2 and the fourth channel portion CR4, whereby the semiconductor device 100 of the present invention is configured with a charge carrier path having a 3D shape. Therefore, as the channel region is further configured along the second (e.g., vertical) direction, the number of charge carriers moving from a source region 122 to a drain region 132 is relatively increased, thereby increasing the current density due to the decrease of the specific on-resistance Rsp.

Referring back to FIG. 5, a first conductive-type body region 120 is on a first side of the gate 110, preferably in the substrate 102. A doping concentration of the body region 120 may be higher than a doping concentration of the first conductivity-type substrate 102 to prevent a depletion region from becoming larger than a predetermined level, thereby facilitating channel formation.

In the body region 120, a second conductive-type source region 122 is in the semiconductor substrate 102 and at the surface of the semiconductor substrate 102 and a first conductive-type body contact region 124 is adjacent to the source region 122. The body contact region 124 may be a P+doped region having a doping concentration higher than that of the body region 120.

A second conductive-type drift region 130 is on a second side of the gate 110 (e.g., in the substrate 102 and at the surface of the substrate 102). A second conductive-type impurity region may serve as the drift region 130. When the doping concentration in the drift region 130 is lower than a predetermined level, the specific on-resistance (Rsp) characteristics deteriorate. On the other hand, when the doping concentration is increased to a predetermined level or higher, the specific on-resistance (Rsp) characteristics are improved but the breakdown voltage characteristics deteriorate. Thus, it may be advantageous to provide an impurity region having an appropriate level of doping or doping concentration in consideration of the characteristics. In some embodiments, the doping concentration of the drift region 130 may be lower than that of the drain region 132.

The drain region 132 is in the drift region 130 (e.g., in the substrate 102 and at the surface of the substrate 102 in the drift region 130). A high concentration impurity region of the second conductive type may serve as the drain region 132, and the drain region 132 has a higher doping concentration than the drift region 130.

In addition, the field oxide 140 is between a lower side of the gate 110 and the drain region 132 to prevent the electric field from concentrating at the edge of the gate 110. The field oxide 140 and the plate region (e.g., a region where the field oxide 140 is on the substrate 102) may be oriented along the first (e.g., horizontal) direction, as described above. In addition, as the field oxide 140 is partly below the gate section 110, the overlapping region between the gate and the field oxide is formed (see, e.g., FIG. 4).

In addition, as described above, the isolation layer 150 may be along the edge of the device 100 to define the active region of the substrate 102. The isolation layer 150 may be formed by the STI method.

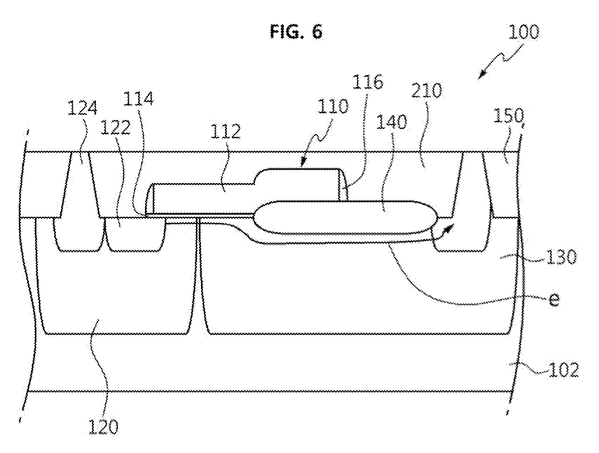

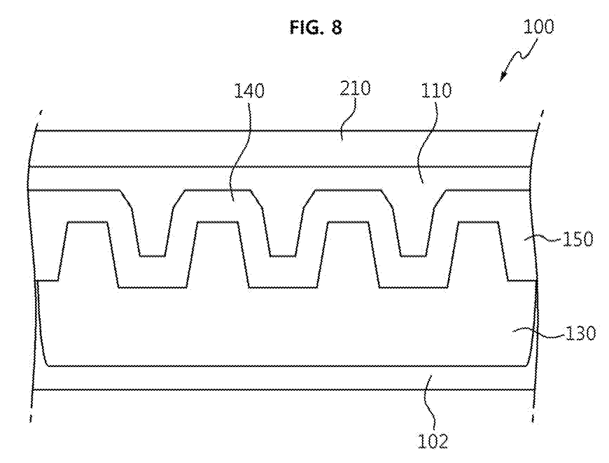

Furthermore, referring to FIGS. 6 to 8, an interlayer dielectric layer 210 may be on or over the semiconductor substrate 102 and the gate 110. The dielectric layer 210 may be or comprise a pre-metal dielectric (PMD) in that the dielectric layer 210 is formed before forming a wiring layer (not shown). The wiring layer is on the dielectric layer 210. The dielectric layer 210 may comprise or be made of a material commonly used in the art, but is not limited thereto.

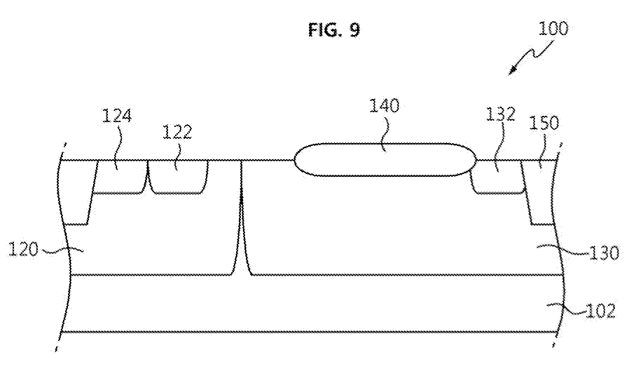

FIGS. 9 to 12 are diagrams illustrating a method of manufacturing a semiconductor device, according to embodiments of the present invention.

Hereinafter, a method of manufacturing a semiconductor device having a 3D channel region, according to embodiments of the present invention will be described in detail with reference to the accompanying drawings.

Referring to FIG. 9, a photoresist pattern (not shown) is formed on the substrate 102 to define a well region, and a well region may be formed by an ion implantation process in which the photoresist pattern is used as an ion implantation mask. In addition, the well region may have the second conductive type. For example, the second conductive type region may be formed by performing the ion implantation process using n-type dopants such as arsenic ions and phosphorus ions and then a heat treatment (annealing) process may be involved. As described above, the substrate 102 may be a p-type doped substrate, a p-type diffusion region in the substrate, or a p-type epitaxial layer epitaxially grown on the substrate.

Thereafter, the photoresist pattern is removed, for example, by an ashing and stripping process, and the isolation layer 150 is formed, whereby the active region can be defined. As described above, the isolation layer 150 may be formed by the STI method.

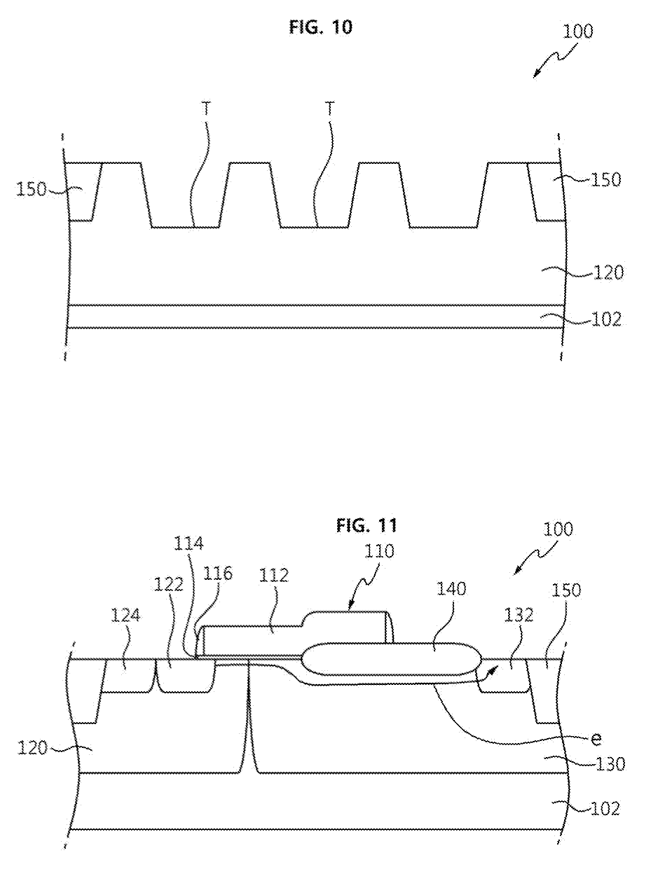

Referring to FIG. 10, in order to form the plurality of trenches T in the semiconductor substrate 102, the photoresist pattern may extend in the first direction on the substrate 102 with portions spaced apart from each other at a predetermined distance. The plurality of trenches T are formed in the surface of the substrate 102, spaced apart from each other horizontally by etching the semiconductor substrate 102 exposed by the photoresist pattern.

Referring back to FIG. 9, a photoresist pattern (not shown) for forming the drift region 130 is formed on the surface of the active region, and the second conductive type drift region 130 may be formed by performing, for example, an ion implantation process.

Thereafter, the field oxide 140 is formed on the plate region by performing a local oxidation of silicon (LOCOS) process.

In addition, referring to FIG. 11, the gate dielectric layer 114 is formed on the substrate 102, specifically on the gate formation region (e.g., a region where the gate 110 is subsequently formed on the substrate 102). A gate film made of a conductive polysilicon film may be deposited to form the gate electrode 112 on the gate dielectric layer 114. It should be noted that the gate film may comprise or be made of a material selected from the group consisting of conductive polysilicon, metal, a conductive metal nitride, and combinations thereof. In addition, the gate dielectric layer 114 may comprise a material selected from the group consisting of a silicon oxide film, a high-κ dielectric film, and a combination thereof.

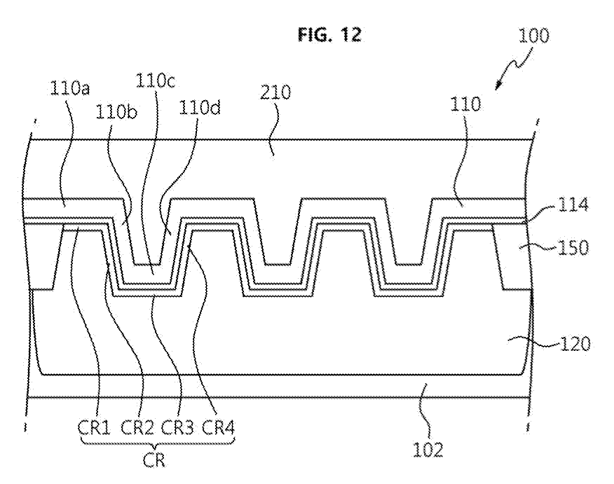

Referring to FIG. 12, with respect to the gate formation region outside the overlapping region, the gate electrode 112 and the gate dielectric layer 114 extend along and across the plurality of trenches T that are spaced apart from each other such that the gate electrode 112 and the gate dielectric layer 114 form the gate (e.g., the repeating first to fourth gate regions 110a to 110d).

Accordingly, the first to fourth channel portions CR1 to CR4 are formed having a 3D path. As a result, the number of charge carriers moving to the channel region is relatively high, contributing to an improvement in the current density due to the decrease of the specific on-resistance Rsp.

The layer for the gate 110 is etched in a region corresponding to the body region 120.

After a photoresist pattern (not shown) is formed on the substrate and the gate 110, the first conductive-type body region 120 may be formed by performing, for example, an ion implantation process, in which the photoresist pattern is used as an ion implantation mask.

In addition, another photoresist pattern is formed on an upper surface of the substrate except for locations where the source region 122 and the drain region 132 are formed. Then, the source region 122 and the drain region 132 of the second conductivity-type are respectively formed, in which an ion implantation is performed through the exposed surface of the semiconductor substrate 102 exposed to the outside.

Thereafter, a photoresist pattern is on the upper surface of the substrate except for a where the body contact region 124 is formed, and the body contact region 124 of the first conductivity type is formed by, for example, an ion implantation process.

The foregoing description of the invention illustrates and describes the present invention. Additionally, the disclosure shows and describes only the preferred embodiments of the invention, but as aforementioned, it is to be understood that the invention is capable of use in various other combinations, modifications, and environments and is capable of changes or modifications within the scope of the inventive concept as expressed herein, commensurate with the above teachings, and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A semiconductor device having a three-dimensional (3D) channel region, the device comprising:
a first conductive-type semiconductor substrate;
a gate on or above the substrate;
a first conductive-type body region on a first side of the gate;
a second conductive-type drift region on a second side of the gate;
a second conductive-type source region in the body region; and
a second conductive-type drain region in the drift region,
wherein a lower surface of the gate extends vertically, such that the gate has a 3D path.

2. The device of claim 1, further comprising:
a 3D channel region below the gate.

3. The device of claim 2, wherein the gate includes:
a plurality of vertically extended regions.

4. The device of claim 3, further comprising:
a channel portion below the plurality of vertically extended regions.

5. The device of claim 4, wherein the gate includes:
a gate dielectric layer in a predetermined pattern on the substrate; and
a gate electrode on the gate dielectric layer.

6. A semiconductor device having a three-dimensional (3D) channel region, the device comprising:
a first conductive-type semiconductor substrate;
a gate on or above the substrate;
a first conductive-type body region on a first side of the gate;
a second conductive-type drift region on a second side of the gate;
a second conductive-type source region on the substrate and in the body region; and
a second conductive-type drain region on the substrate and in the drift region,
wherein the gate includes:
a plurality of vertically extended regions.

7. The device of claim 6, wherein the gate further includes:
a plurality of horizontally extended regions, each connected to an end of at least one of the vertically extended regions.

8. The device of claim 7, wherein the gate includes:
a gate dielectric layer in a predetermined pattern on the substrate; and
a gate electrode on the gate dielectric layer.

9. The device of claim 7, further comprising:
in the body region, a first channel portion below the plurality of horizontally extended regions; and
a second channel portion below the plurality vertically extended regions.

10. A method of manufacturing a semiconductor device having a 3D channel region, the method comprising:
forming a plurality of trenches in a substrate;
forming a drift region in the substrate;
depositing a gate dielectric layer and a gate film on the substrate and in the trenches; and
etching the gate film corresponding to a first conductive-type body region and forming the body region.

11. The method of claim 10, wherein the gate dielectric layer and a gate electrode extend vertically and the gate dielectric layer and the gate electrode have a 3D path.

12. The method of claim 11, further comprising:
forming a source region in the substrate in the body region; and
forming a drain region in the substrate in the drift region.

13. The method of claim 12, further comprising a channel region having a 3D charge carrier movement path.

14. A method of manufacturing a semiconductor device having a 3D channel region, the method comprising:
forming a plurality of trenches in a substrate and spaced apart from each other;
forming a drift region on the substrate;
depositing a gate dielectric layer and a gate film on the substrate and the gate formation region having the plurality of trenches;
forming a body region on the substrate; and
forming a gate by etching the gate dielectric layer and the gate film,
wherein a portion of the gate which is on an upper portion of the trenches includes:
a plurality of vertically extended regions.

15. The method of claim 14, further comprising:
forming a source region adjacent to an upper surface of the substrate and in the body region; and
forming a drain region adjacent to the upper surface of the substrate and in the drift region.

16. The method of claim 15, further comprising forming a channel region, the channel region including a second channel portion below the plurality of vertically extended regions.

17. The method of claim 16, wherein the gate is in the gate formation region outside the upper portion of the plurality of trenches, further comprises:
a plurality of horizontally extended regions and connected to at least an end of the vertically extended regions.

18. The method of claim 17, wherein the channel region further comprising:
a channel portion below the plurality of horizontally extended regions.

19. The semiconductor device of claim 1, further comprising:
a field oxide between a lower side of the gate and the drain region;
wherein the gate overlaps the field oxide.
